(19) United States
(12) Patent Application Publication
(10) Pub. No.: US 2007/0145483 A1
(43) Pub. Date: Jun. 28, 2007

(54) Semiconductor device

(75) Inventor: Mizuki Ono, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/640,929

(22) Filed: Dec. 19, 2006

(30) Foreign Application Priority Data
Dec. 28, 2005 (JP) 2005-378682

(51) Int. Cl. H01L 27/12

(52) U.S. Cl. 257/353

(57) ABSTRACT

A highly-integrated, high-performance semiconductor device with a simplest possible structure can be provided. This semiconductor device comprises a semiconductor element that includes: a first semiconductor region of a first conductivity type provided in a plate-like form on a semiconductor substrate; a first ferroelectric insulating film provided on a first side face of the first semiconductor region; a first gate electrode provided on the opposite face of the first ferroelectric insulating film from the first semiconductor region; a second ferroelectric insulating film provided on a second side face of the first semiconductor region; a second gate electrode provided on the opposite face of the second ferroelectric insulating film from the first semiconductor region; a channel region formed in the first semiconductor region and interposed between the first and second gate electrodes; and first source/drain regions of a second conductivity type provided at portions in the first semiconductor region located on both sides of the channel region. In this semiconductor element, the thickness of the first semiconductor region is smaller than twice the largest thickness of a depletion layer that is determined by the impurity concentration of the first semiconductor region.

### CROSS-REFERENCE TO RELATED APPLICATION

This application is based upon and claims the benefit of priority from prior Japanese Patent Application No. 2005-378682 filed on Dec. 28, 2005 in Japan, the entire contents of which are incorporated herein by reference.

### BACKGROUND OF THE INVENTION

1. Field of the Invention

The present invention relates to a semiconductor device.

2. Related Art

Along with a demand for logic semiconductor devices capable of performing more complicated information processing, there has been a demand for simpler circuits or higher integration. Particularly, there is an increasing demand for reconfigurable logic semiconductor devices, as quick responses to changes in logic specifications are required and there are possibilities that the logic functions are changed by users. In a conventional reconfigurable logic semiconductor device, a particular control signal is read out in accordance with the combination of input signals. JP-A 2005-127772 (KOKAI) discloses such an example in which there are two input signals. By this method, an output of a desired value in accordance with the combination of input signals can be set by switching control signals.

The number of field effect transistors required for constructing the reconfigurable logic semiconductor device disclosed in the above described document is 34 in total: six for selecting a control signal, four for two inverters (two each), and 24 for four input signals if a SRAM is used for control signals (six each). Because of this large number of field effect transistors, the structure of the reconfigurable logic semiconductor device is complicated, and it is difficult to reduce the area occupied by the field effect transistors. This fact hinders the production of highly-integrated structures.

### SUMMARY OF THE INVENTION

A semiconductor device according to a first aspect of the present invention includes: a semiconductor element that includes a first semiconductor region of a first conductivity type provided in a plate-like form on a semiconductor substrate; a first ferroelectric insulating film provided on a first side face of the first semiconductor region; a first gate electrode provided on the opposite face of the first ferroelectric insulating film from the first semiconductor region; a second ferroelectric insulating film provided on a second side face of the first semiconductor region; a second gate electrode provided on the opposite face of the second ferroelectric insulating film from the first semiconductor region; a channel region formed in the first semiconductor region and interposed between the first and second gate electrodes; and first source/drain regions of a second conductivity type provided at portions in the first semiconductor region located on both sides of the channel region, the first semiconductor region having a thickness smaller than twice the largest thickness of a depletion layer that is determined by impurity concentration of the first semiconductor region.

A semiconductor device according to a second aspect of the present invention includes: a first semiconductor element and a second semiconductor element, the first semiconductor element including: a first semiconductor region of a first conductivity type provided in a plate-like form on a semiconductor substrate; a first ferroelectric insulating film provided on a first side face of the first semiconductor region; a first gate electrode provided on the opposite face of the first ferroelectric insulating film from the first semiconductor region; a second ferroelectric insulating film provided on a second side face of the first semiconductor region; a second gate electrode provided on the opposite face of the second ferroelectric insulating film from the first semiconductor region; a first channel region formed in the first semiconductor region and interposed between the first and second gate electrodes; and first source/drain regions of a second conductivity type provided at portions in the first semiconductor region located on both sides of the first channel region, the first semiconductor region having a thickness smaller than twice the largest thickness of a depletion layer that is determined by impurity concentration of the first semiconductor region, the second semiconductor element including: a second semiconductor region of the second conductivity type provided in a plate-like form on the semiconductor substrate; a third ferroelectric insulating film provided on a first side face of the second semiconductor region; a third gate electrode provided on the opposite face of the third ferroelectric insulating film from the second semiconductor region; a fourth ferroelectric insulating film provided on a second side face of the second semiconductor region; a fourth gate electrode provided on the opposite face of the fourth ferroelectric insulating film from the second semiconductor region; a second channel region formed in the second semiconductor region and interposed between the third and fourth gate electrodes; and second source/drain regions of the first conductivity type provided at portions in the second semiconductor region located on both sides of the second channel region, the second semiconductor region having a thickness smaller than twice the largest thickness of a depletion layer that is determined by impurity concentration of the second semiconductor region, and one of the first source/drain regions being electrically connected to one of the second source/drain regions, one of the first and second gate electrodes being electrically connected to one of the third and fourth gate electrodes, the other one of the first and second gate electrodes being electrically connected to the other one of the third and fourth gate electrodes.

### BRIEF DESCRIPTION OF THE DRAWINGS

FIG. 1 is a perspective view of a semiconductor element according to a first embodiment of the present invention;

FIG. 2 is a cross-sectional view of the semiconductor element of the first embodiment, cut off taken along the section line B-B′ of FIG. 1;

FIG. 3 illustrates a procedure for manufacturing the semiconductor element of the first embodiment;

FIG. 4 illustrates a procedure for manufacturing the semiconductor element of the first embodiment;

FIG. 5 illustrates a procedure for manufacturing the semiconductor element of the first embodiment;

FIG. 6 illustrates a procedure for manufacturing the semiconductor element of the first embodiment;

FIG. 7 is a cross-sectional view of the semiconductor element according to a modification of the first embodiment;

FIG. 8 is a perspective view of a semiconductor element according to a modification of the first embodiment;

FIG. 9 is a circuit diagram of a circuit according to a second embodiment of the present invention;

FIG. 10 explains the notation in the circuit diagram of the semiconductor element of the first embodiment;

FIG. 11 is a circuit diagram of a circuit according to a third embodiment of the present invention;

FIG. 12 is a circuit diagram of a circuit according to a fourth embodiment of the present invention;

FIG. 13 is a cross-sectional view of a semiconductor element according to a fifth embodiment of the present invention; and

FIG. 14 is a perspective view of a conventional Fin-type field effect transistor.

### DETAILED DESCRIPTION OF THE INVENTION

The following is a description of embodiments of the present invention, with reference to the accompanying drawings. It should be noted that the present invention is not limited to the following embodiments, but various changes and modification may be made to those embodiments.

### First Embodiment

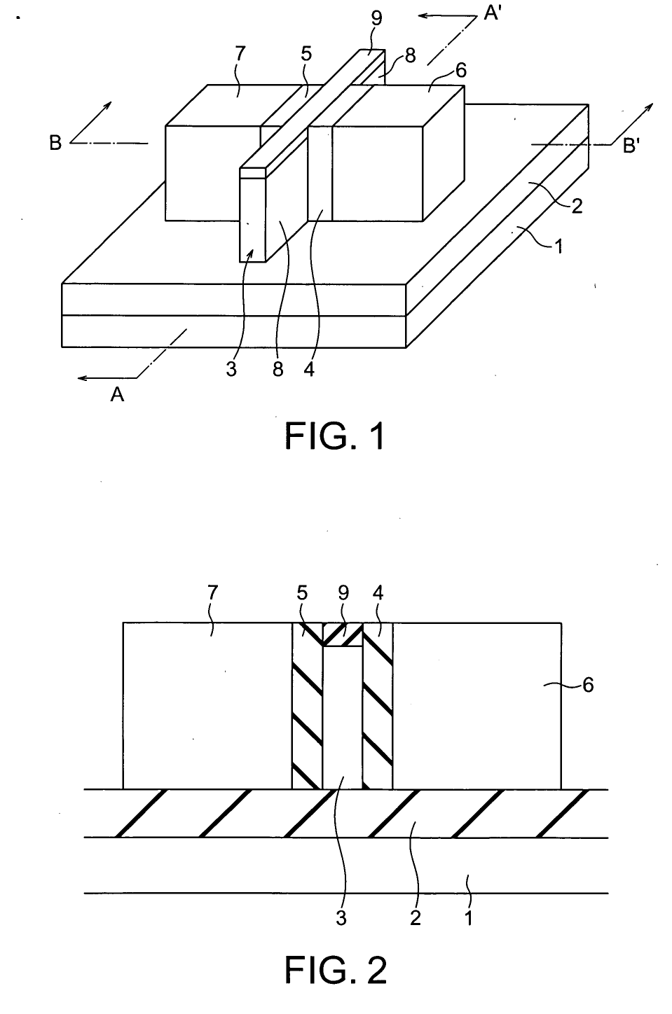

FIG. 1 is a schematic view of a semiconductor element in accordance with a first embodiment of the present invention. This semiconductor element is formed on a SOI substrate, and a plate-like semiconductor region to form a channel region is formed on an embedded insulating film 2 formed on the supporting semiconductor substrate 1. First and second gate electrodes 6 and 7 are formed to sandwich the semiconductor region 3 via first and second ferroelectric insulating films 4 and 5. The plate-like semiconductor region 3 to form the channel region extends behind the gate electrodes 6 and 7, and source/drain regions 8 are formed on the front side and the back side in the drawing, so as to sandwich the gate electrodes 6 and 7. An insulating film 9 is formed on the plate-like semiconductor region 3 that serves as the channel region. The principal direction of the current flowing through the channel is the direction indicated by the line A-A′. FIG. 2 is a cross-sectional view of the semiconductor element, taken along the line B-B′ of FIG. 1. In FIGS. 1 and 2, the interlayer insulating film, the metal wirings, the junction regions between the metal wirings and the source/drain regions, and the junction regions between the metal wirings and the gate electrodes are not shown.

The thickness of the semiconductor region 3 to form the channel region is thinner than twice the largest thickness of the depletion layer that is determined by the impurity concentration. Polarization of the ferroelectric insulating films 4 and 5 can be controlled by applying a predetermined potential to the gate electrodes 6 and 7 or the source/drain regions 8. In this manner, a logic circuit can be formed far more easily than a conventional semiconductor element. This fact is described below in greater detail.

First, an n-type semiconductor element, or a semiconductor element that has p-type impurities contained in the channel region and n-type impurities contained in the source/drain regions is taken as an example. The thickness of the channel region of a semiconductor element in accordance with this embodiment is thinner than twice the largest thickness of the depletion layer determined by the impurity concentration. Accordingly, inversion layers are not formed independently of each other on the side faces of the channel region on which the gate electrodes exist, but inversion layers are formed on the entire semiconductor region 3 that serves as the channel region, depending on the combination of the potentials of both gate electrodes 6 and 7. In an n-type semiconductor device, if the polarization of the ferroelectric insulating films 4 and 5 forming the gate insulating film is directed to the channel from the gate electrodes 6 and 7, the semiconductor device becomes ON at a lower gate voltage. If the polarization of the ferroelectric insulating films 4 and 5 is directed to the gate electrodes 6 and 7 from the channel, the semiconductor device becomes ON at a higher gate voltage. Therefore, with the power supply voltage being set at 1 and the ground voltage being set at 0 as the potentials of the gate electrodes 6 and 7, the semiconductor device becomes ON with an “OR” of the two gate electrodes 6 and 7 in the case where the polarization of the ferroelectric insulating films 4 and 5 is directed to the channel from the gate electrodes 6 and 7. In the case where the polarization of the ferroelectric insulating films 4 and 5 is directed to the gate electrodes 6 and 7 from the channel, the semiconductor device becomes ON with an “AND” of the two gate electrodes 6 and 7. In this specification, the “largest thickness of the depletion layer that is determined by the impurity concentration in the region” is defined as the thickness of the depletion layer that is formed in a case where a voltage equal to the value obtained by dividing the forbidden band width (1.1 eV in the case of silicon, for example) of a semiconductor forming a substrate by the elementary charge is applied on the surface to an inner portion of a semiconductor substrate having a sufficient thickness containing impurities with the same concentration.

Since a circuit that becomes ON with an “AND” or “OR” of two inputs using conventional n-type field effect transistors is to be formed, a series-connected structure of two n-type field effect transistors needs to be produced so as to form a circuit that becomes on with an “AND”, while a parallel-connection structure of two n-type field effect transistors needs to be produced so as to form a circuit that becomes on with an “OR”.

In accordance with this embodiment, however, such a circuit can be realized by one semiconductor element having a far simpler structure. This is a fact discovered by the inventor of the present invention. Furthermore, only the direction of the polarization of the ferroelectric insulating films 4 and 5 determines whether a semiconductor element of this embodiment becomes ON with an “AND” of the two inputs or with an “OR” of the two inputs. Therefore, the polarization is inverted by adjusting the potentials of the gate electrodes 6 and 7 or the source/drain regions 8, so that the semiconductor element can be controlled to be ON with an “AND” or “OR”. This is also a fact discovered by the inventor of the present invention.

Next, a p-type semiconductor element, or a semiconductor element having n-type impurities contained in the channel region and p-type impurities contained in the source/drain regions is taken as an example. The thickness of the channel region of a semiconductor element in accordance with this embodiment is thinner than twice the largest thickness of the depletion layer determined by the impurity concentration. Accordingly, inversion layers are not formed independently of each other on the side faces of the channel region on which the gate electrodes exist, but inversion layers are formed on the entire semiconductor region 3 that serves as the channel region, depending on the combination of the potentials of both gate electrodes 6 and 7. In a p-type semiconductor device, if the polarization of the ferroelectric insulating films 4 and 5 forming the gate insulating film is directed to the channel from the gate electrodes 6 and 7, the semiconductor device becomes ON at a lower gate voltage. If the polarization of the ferroelectric insulating films 4 and 5 is directed to the gate electrodes 6 and 7 from the channel, the semiconductor device becomes ON at a higher gate voltage. Therefore, with the power supply voltage being set at 1 and the ground voltage being set at 0 as the potentials of the gate electrodes 6 and 7, the semiconductor device becomes ON with a “NOR” of the two gate electrodes 6 and 7 in the case where the polarization of the ferroelectric insulating films 4 and 5 is directed to the channel from the gate electrodes 6 and 7. In the case where the polarization of the ferroelectric insulating films 4 and 5 is directed to the gate electrodes 6 and 7 from the channel, the semiconductor device becomes ON with a “NAND” of the two gate electrodes 6 and 7. This is also a fact discovered by the inventor of the present invention.

Furthermore, only the direction of the polarization of the ferroelectric insulating films 4 and 5 determines whether a semiconductor element of this embodiment becomes ON with a “NAND” of the two inputs or with a “NOR” of the two inputs. Therefore, the polarization is inverted by adjusting the potentials of the gate electrodes 6 and 7 or the source/drain regions 8, so that the semiconductor element can be controlled to be ON with a “NAND” or “NOR”. This is also a fact discovered by the inventor of the present invention.

As described above, a semiconductor element of this embodiment can form a logic circuit with a far simpler structure than a conventional semiconductor element.

Next, a method for manufacturing a semiconductor element in accordance with this embodiment is described.

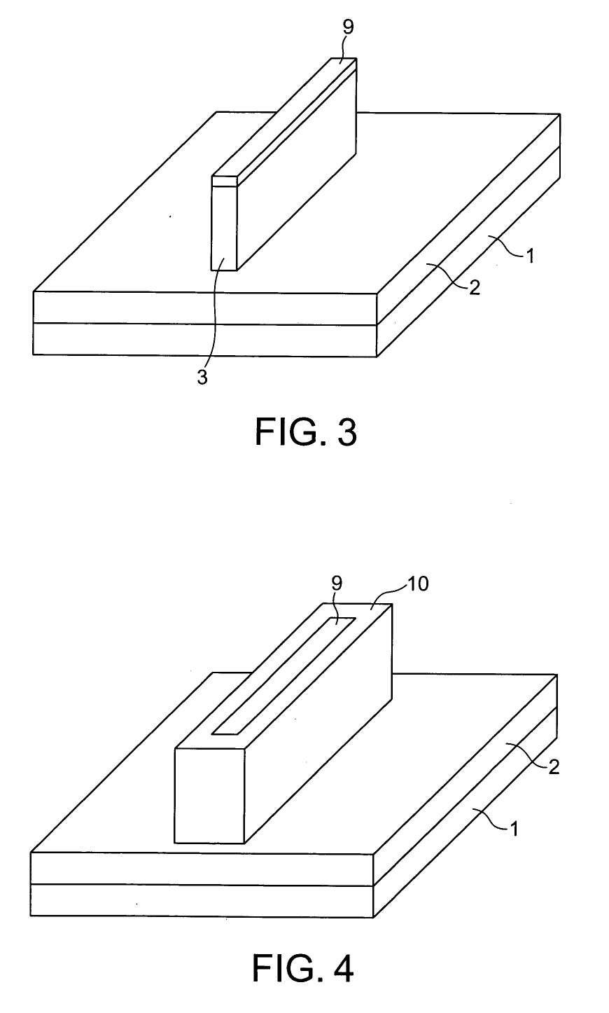

First, as shown in FIG. 3, B (Boron) ions are injected with energy of 30 keV and a concentration of 1×10¹² cm⁻² to a semiconductor layer of a SOI substrate. A heating process is then carried out at 1050° C. for 30 seconds, for example. A silicon oxide film of 30 nm in thickness is formed on the semiconductor layer by chemical vapor deposition (hereinafter referred to as CVD), for example. Anisotropic etching such as reactive ion etching (hereinafter referred to as RIE) is then performed on the entire surface of the semiconductor substrate including the silicon oxide film, so as to form the semiconductor region 3 that serves as the channel region and the insulating film 9 on the semiconductor region 3.

As shown in FIG. 4, a PZT film (PbZrₓTi₁₋ₓO₃) of 20 nm in thickness is then formed on the entire surface of the semiconductor substrate including the semiconductor region 3 forming the channel region by CVD or the like. Anisotropic etching such as RIE is performed on the PZT film, so as to form a sidewall 10 formed with a ferroelectric insulating film.

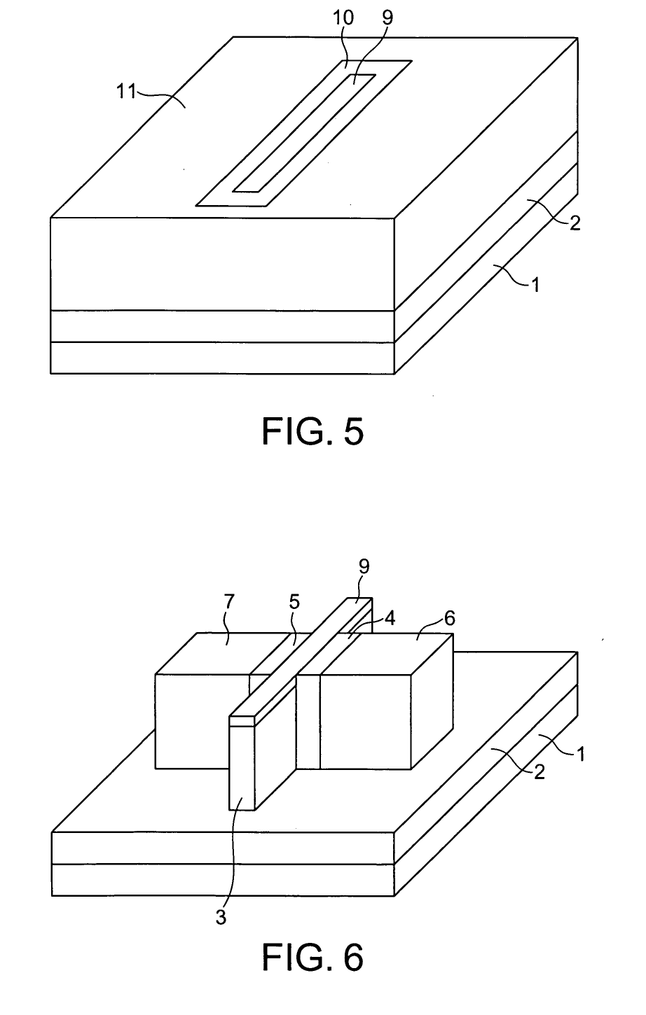

As shown in FIG. 5, a W (tungsten) film 11 of 100 nm in thickness is then formed on the entire surface of the semiconductor substrate including the semiconductor region 3 as the channel region, the insulating film 9, and the sidewall 10, by CVD or the like. The surface of the W film 11 is then flattened by chemical mechanical polishing (hereinafter referred to as CMP), so as to expose the upper faces of the insulating film 9 and the sidewall 10.

As shown in FIG. 6, patterning is performed on the W film 11 through anisotropic etching such as RIE, so as to form the first and second gate electrodes 6 and 7. Patterning is again performed on the sidewall 10 formed with a ferroelectric insulating film through anisotropic etching such as RIE, so as to form the first and second ferroelectric insulating films 4 and 5.

As (Arsenic) ions are then injected with energy of 5 keV and a concentration of 1×10¹⁵ cm⁻², for example, and a heating process is carried out to form the source and drain regions 8.

After that, the semiconductor element of this embodiment is completed through an interlayer insulating film forming procedure and a wiring procedure as in the case of forming a conventional semiconductor element.

Although an n-type semiconductor element has been taken as an example in this embodiment, this embodiment can be applied to a p-type semiconductor element by reversing the conductivity types of impurities and to a complementary semiconductor element by introducing impurities only to a particular region in the substrate by photolithography or the like. Further, this embodiment can be applied to a semiconductor element partially having one of the above features.

Although only the procedures for forming a semiconductor element have been described in this embodiment, the same procedures as above may be carried out to form a part of an integrated circuit containing an active element such as a field effect transistor, a bipolar transistor, or a single-electron transistor, a passive element such as a resistor, a diode, an inductor, or a capacitor, or a part of a semiconductor device including an element using a ferroelectric body, an element using a magnetic body, or a memory device. The same procedures may be carried out to form a part of an OEIC (opto-electrical integrated circuit) or a MEMS (micro electro mechanical system).

Although the semiconductor element of this embodiment is formed on a SOI substrate, it may be formed on a regular bulk semiconductor substrate, to achieve the same effects as above.

In this embodiment, As ions are used as the impurities to form an n-type semiconductor layer, and B ions are used as the impurities to form a p-type semiconductor layer. However, it is also possible to employ other V-group impurities as the impurities to form an n-type semiconductor layer, or employ other III-group impurities as the impurities to form a p-type semiconductor layer. The introduction of III-group or V-group impurities may be carried out with a compound containing those impurities.

Although the introduction of the impurities is performed through ion implantation in this embodiment, methods other than ion implantation such as solid-phase diffusion and gas-phase diffusion may also be used. Moreover, methods of depositing or developing semiconductors containing impurities may also be used.

In this embodiment, impurity introduction to adjust the threshold voltage of the element is not performed. However, it is possible to perform impurity introduction to adjust the threshold voltage independently of the impurity introduction for the well formation. In this manner, the threshold voltage can be readily adjusted to a desired value. This embodiment has the advantage in simpler procedures.

Furthermore, an element including a single drain structure has been described as an example of this embodiment. However, the elements including structures other than the single drain structure, such as an extension structure, a lightly-doped drain (LDD) structure, a graded diffused source/drain (GDD) structure may also be constructed. Alternatively, an element including a halo or pocket structure may be employed, because an element having such a structure has higher resistance to a short-channel effect. Also, the source/drain regions may be made of a metal, metal silicate, or the like, so as to form a so-called Schottky element.

In this embodiment, the source/drain regions are formed after the processing of the gate electrodes and the gate insulating films. However, this order is not essential, but may be reversed. Depending on the materials of the gate electrodes and the gate insulating films, there may be a case where a heating process is not preferable. In such a case, the introduction of impurities to the source/drain regions and the heating process for activation should preferably be carried out before the processing of the gate electrodes and the gate insulating films.

Although the gate electrodes are made of W in this embodiment, they may be formed with a semiconductor such as a single crystalline silicon semiconductor or a noncrystalline silicon semiconductor, a metal other than W, a compound containing a metal, or a stacked film of those materials. A metal or a compound containing a metal can lower the resistance of the gate electrodes. Accordingly, high-speed performance can be expected from the element. Also, the gate electrodes made of a metal can restrict oxidation reaction, and can advantageously increase the controllability at the interface between the ferroelectric insulating films and the gate electrodes. Further, with a semiconductor such as a polycrystalline silicon semiconductor being used at least as a part of the gate electrodes, the control of the work function becomes easier, and the threshold voltage can be advantageously adjusted with ease.

In this embodiment, the gate electrodes are formed by performing anisotropic etching after the deposition of the materials of the gate electrodes. However, an embedding technique such as the damascene process may be utilized to form the gate electrodes. In the case where the source/drain regions are formed before the formation of the gate electrodes, the use of the damascene process is preferable because the source/drain regions and the gate electrodes are formed in a self-aligned manner.

In this embodiment, the lengths of the upper portion and the lower portion of each gate electrode measured in the principal direction of the current flowing through the element are the same, but this is not an essential factor. For example, each gate electrode may have a T-like shape, with the upper portion being longer than the lower portion. In such a case, the gate resistance can be advantageously reduced.

Although not described in this embodiment, the formation of the metal layer for wirings may be carried out by a sputtering technique or a deposition technique or the like. Alternatively, a metal selective growth technique or the damascene process may be utilized. The material of the wirings may be a metal such as an Al (aluminum) material containing silicon or Cu (copper). Especially, Cu is preferred, having a lower resistivity.

Although a silicidation procedure has not been described in this embodiment, a silicide layer may be formed on the source/drain regions. Alternatively, a layer containing a metal may be deposited or grown on the source/drain regions. With this arrangement, the resistance in the source/drain regions is preferably reduced. In a case where the gate electrodes are made of polycrystalline silicon, silicidation may be performed on the gate electrodes. Silicidation is preferable, lowering the gate resistance. An elevated structure may also be employed. With an elevated structure, the resistance in the source/drain regions is advantageously lowered.

In this embodiment, the upper portion of each gate electrode is exposed. However, an insulator such as silicon oxide, silicon nitride, or silicon oxynitride may be provided on the upper portion of each gate electrode. Particularly, in a case where the gate electrodes are made of a material containing a metal and a silicide layer is formed on the source/drain regions, and therefore, the gate electrodes need to be protected during the manufacturing process, it is necessary to provide a protection material such as silicon oxide, silicon nitride, or silicon oxynitride on the upper portion of each gate electrode.

Although PZT film formed through deposition is used for the ferroelectric insulating films in this embodiment, it is also possible to use other ferroelectric materials such as PLZT (PbₓLa₁₋ₓZr_{y}Ti_{1-y}O₃) or SBT (SrBi₂Ta₂O₉). The film formation method is not limited to deposition, but some other method such as a sputtering method may be utilized.

Although gate sidewalls have not been mentioned in this embodiment, it is possible to provide sidewalls for the gate electrodes. Particularly, if gate sidewalls made of a high-dielectric-constant material are provided, the electric field induced in the ferroelectric insulating films in the vicinity of the lower ends of the gate electrodes is made less intensive, as disclosed in Japanese Patent No. 3658564. Accordingly, the reliability of the ferroelectric insulating films can be advantageously increased.

Although post oxidation after the formation of the gate electrodes has not been mentioned in this embodiment, a post oxidizing procedure may be carried out if possible, with the materials of the gate electrodes and the ferroelectric insulating films being taken into consideration. Other than post oxidation, a process for rounding the edges of the lower ends of the gate electrodes may be carried out with the use of a chemical solution or by exposing the lower ends to a reactive gas. If such procedures are possible, the electric field at the edges of the lower ends of the gate electrode is made less intensive, and accordingly, the reliability of the ferroelectric insulating films is advantageously increased.

Although not mentioned in this embodiment, a silicon oxide film may be employed as the interlayer insulating film, or a material other than silicon oxide, such as a low-dielectric-constant material, may be employed for the interlayer insulating film. As the dielectric constant of the interlayer insulating film is made smaller, the parasitic capacitance of the element is reduced. Thus, high-speed performance can be expected from the element.

Although contact holes have not been mentioned in this embodiment, it is possible to form self-aligned contacts. With self-aligned contacts, the area of the element can be reduced, and the integration rate can be advantageously increased.

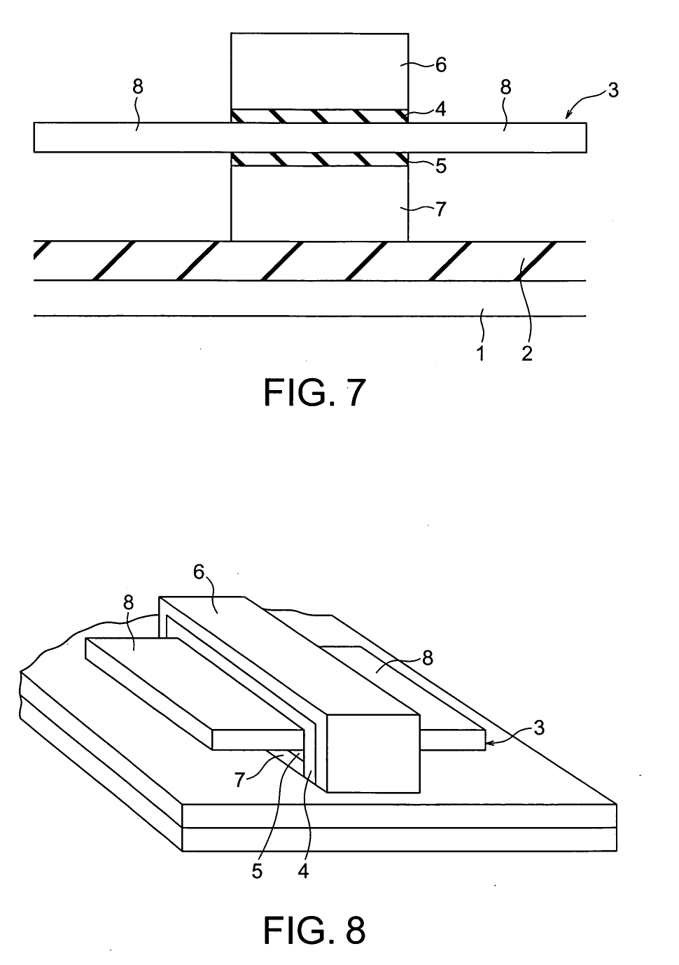

In this embodiment, the principal direction of the current flowing through the semiconductor region serving as the channel region is parallel to the surface of the semiconductor substrate 1, and the gate electrodes 6 and 7 are designed to sandwich the semiconductor region at both sides. However, the gate electrodes 6 and 7 may be formed to sandwich the semiconductor region 3 serving as the channel region at the top and the bottom, as shown in FIG. 7.

A semiconductor element having the structure shown in FIG. 7 is produced by stacking a second gate electrode film and a second ferroelectric insulating film in this order on a semiconductor substrate 1 having an insulating film 2 formed thereon, and forming a second gate electrode 7 and a second ferroelectric insulating film 5 through patterning. A sacrifice film (not shown) is formed and flattened by CMP or the like, so as to expose the upper surface of the second ferroelectric insulating film 5. A p-type semiconductor layer 3 is then formed. A first ferroelectric insulating film and a first gate electrode film are stacked in this order on the semiconductor layer 3, and patterning is performed to form the first ferroelectric insulating film 4 and a first fate electrode 6. Source/drain regions 8 are then formed by introducing n-type impurities to the portions of the semiconductor layer located at both sides of the first gate electrode 6.

In the semiconductor element shown in FIG. 7 and manufactured as described above, to maintain the electric insulation of the first gate electrode 6 from the semiconductor region 3 serving as the channel region, the first ferroelectric insulating film 4 needs to be formed on the side faces of the semiconductor region 3 serving as the channel region, as schematically shown in FIG. 8. As a result, the first ferroelectric insulating film 4 and the second ferroelectric insulating film 5 are brought into contact with each other. In this figure, the interlayer insulating film, the metal wirings, the source/drain regions, and the junction regions between the gate electrodes and the metal wirings are not shown. The spontaneous polarization of a ferroelectric material is the consequence of the stabilization achieved when neighboring dipoles are aligned. Accordingly, when the first and second ferroelectric insulating films 4 and 5 are brought into contact with each other as shown in this figure, a stabilized state is achieved through polarization in the same direction in the two ferroelectric insulating films, but a stabilized state is not achieved through polarization caused both in the direction from the gate electrodes 6 and 7 to the semiconductor region 3 serving as the channel region and in the direction from the semiconductor region 3 serving as the channel region to the gate electrodes 6 and 7. Therefore, as described in this embodiment, the principal direction of the current flowing through the semiconductor region 3 serving as the channel should preferably be parallel to the surface of the semiconductor substrate 1, and the gate electrodes should preferably be formed to sandwich the semiconductor region 3 at both sides.

In this embodiment, the gate insulating films are made of a ferroelectric material, and the orientation of the polarization is controlled so as to determine whether the element is to be ON with an “AND” or an “OR”. However, each of the gate insulating films may not be made of a ferroelectric material, but may be formed with a stacked structure of a tunnel gate insulating film, a floating gate electrode, and an inter-poly insulating film. In such a case, the amount of charges stored in the floating gate electrode is adjusted so as to determine whether the element is to be ON with an “AND” or an “OR”. In doing so, however, the equivalent oxide thickness (the thickness of a silicon oxide film having the same capacity per unit area as a parallel plate capacitor formed with the insulating films) of the gate insulating films 4 and 5 becomes the same as the sum of the equivalent oxide thickness of the tunnel gate insulating film and the inter-poly insulating film. Therefore, it is difficult to reduce the equivalent oxide thickness of the gate insulating film, and this hinders miniaturization of the element. With the structure of this embodiment, on the other hand, such difficulties are not caused, and the element can be miniaturized. As a result, a high-performance semiconductor element of a very small size can be advantageously produced.

### Second Embodiment

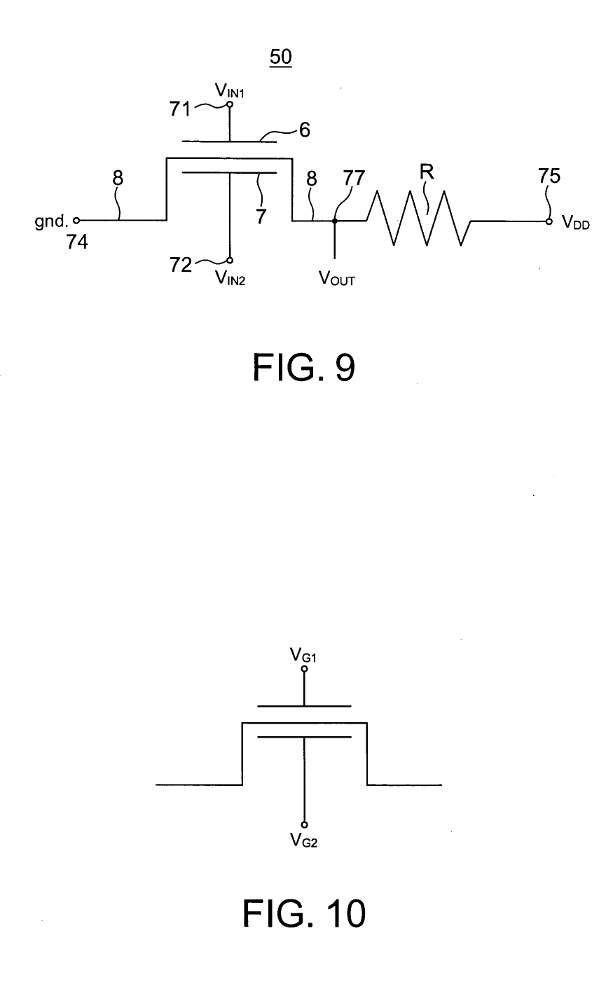

FIG. 9 illustrates a circuit in accordance with a second embodiment of the present invention. The circuit of this embodiment includes the semiconductor element 50 shown in FIG. 1 and a resistor R. This semiconductor element 50 is an n-type semiconductor element, or a semiconductor element that has p-type impurities contained in the semiconductor region that serves as a channel and n-type impurities contained in the source/drain regions. The first and second gate electrodes 6 and 7 of the semiconductor element 50 are connected to first and second input terminals 71 and 72, and potentials V_{IN1} and V_{IN2} are applied to the input terminals 71 and 72, respectively. One of the source/drain regions 8 is connected to a ground terminal 74, and the other one is connected to a potential terminal 75 of a power supply voltage via the resistor R. In FIG. 9, the ground potential is denoted by gnd., and the power supply voltage is denoted by V_{DD}. The source/drain regions 8 and the resistor R are connected with an output terminal 77, and the potential of the junction is denoted by V_{OUT}. In this embodiment and the embodiments described later, the semiconductor element of the first embodiment is shown in a circuit diagram as shown in FIG. 10. The terminals denoted by V_{G1} and V_{G2} in FIG. 10 are the first and second gate electrodes, respectively.

In a case where the polarization of the ferroelectric insulating films is directed from the gate electrodes to the channel region, the circuit of this embodiment becomes ON with an “OR” of the two gate electrodes. Therefore, if both inputs are “0”, which is the ground potential, “1”, which is the power supply voltage, is output to the output terminal. In any other cases, “0”, which is the ground potential, is output to the output terminal. In this example case, the circuit of this embodiment is a NOR circuit.

To form a NOR circuit with conventional n-type field effect transistors, two n-type field effect transistors are connected in parallel, and a series-connected structure of the two n-type field effect transistors and a resistor is formed. Therefore, two field effect transistors are required.

In this embodiment, on the other hand, a NOR circuit can be formed only with one semiconductor element of the first embodiment. Thus, this circuit can be formed through very simple procedures.

In a case where the polarization of the ferroelectric insulating films is directed from the channel region to the gate electrodes, the semiconductor element 50 in the circuit of this embodiment becomes ON with an “AND” of the two gate electrodes. Accordingly, if both inputs are “1”, which is the power supply voltage, “0”, which is the ground potential, is output to the output terminal. In any other cases, “1”, which is the power supply voltage, is output to the output terminal. Thus, the logic circuit of this embodiment becomes a NAND circuit.

To form a NAND circuit with conventional n-type field effect transistors, two n-type field effect transistors are connected in series, and a series-connected structure of the two n-type field effect transistors and a resistor is formed. Therefore, two field effect transistors are required.

In this embodiment, on the other hand, a NAND circuit can be formed only with one semiconductor element of the first embodiment. Thus, this circuit can be formed through very simple procedures. This is a fact discovered by the inventor of the present invention.

The following example case is now described. The circuit of this embodiment is formed as a part of a logic circuit. The terminal connected to the ground potential and the terminal connected to the power supply voltage in the diagram can be connected to a sufficiently high potential and a sufficiently low potential. Determination is to be made as to whether the output terminal in the diagram is to be connected to the logic circuit. When the connection between the output terminal and the logic circuit is cut off, and the terminal connected to the ground terminal and the terminal connected to the power supply voltage in the diagram are set at a sufficiently low potential, an electric field directed from the gate electrodes to the channel region is induced in the ferroelectric insulating films. Accordingly, the polarization is directed from the gate electrodes to the channel region, regardless of the initial state. In this manner, the circuit shown in FIG. 9 becomes a NOR circuit. When the connection between the output terminal and the logic circuit is cut off, and the terminal connected to the ground terminal and the terminal connected to the power supply voltage in the diagram are set at a sufficiently high potential, an electric field directed from the channel region to the gate electrodes is induced in the ferroelectric insulating films. Accordingly, the polarization is directed from the channel region to the gate electrodes, regardless of the initial state. In this manner, the circuit shown in FIG. 9 becomes a NAND circuit. As at least one of the source/drain terminals of the semiconductor element 50 of the first embodiment can be connected to at least three different potentials, the circuit shown in FIG. 9 can be switched between a NOR circuit and a NAND circuit. Thus, a reconfigurable logic circuit can be formed with one element.

As mentioned in “Related Art”, a number of field effect transistors are required to form a reconfigurable logic circuit by a conventional technique, resulting in a very complicated structure. With the use of the semiconductor element of the first embodiment, on the other hand, a reconfigurable logic circuit can be formed very easily. This is also a fact discovered by the inventor of the present invention.

Next, the following example case is described. The circuit of this embodiment is formed as a part of a logic circuit. The two input terminals shown in the diagram can be connected to both a sufficiently high potential and a sufficiently low potential. A “sufficiently high potential” and a “sufficiently low potential” are as follows. If an electric field with intensity higher than a predetermined value is applied in the opposite direction from the direction of the polarization caused in the ferroelectric films, the direction of the polarization is reversed. The product of the intensity of this electric field and the thickness of the ferroelectric films are referred to as the coercive voltage. Here, a potential that is higher than the value obtained by adding the power supply voltage of the logic circuit to the coercive voltage of the ferroelectric films used in the element is referred to as a “sufficiently high potential”, and a potential that is lower than the value obtained by changing the sign of the coercive voltage of the ferroelectric films used in the element is referred to as a “sufficiently low potential”.

When the two input terminals are set at sufficiently high potentials, an electric field directed from the gate electrodes to the channel region is induced in the ferroelectric insulating films. Accordingly, the polarization is directed from the gate electrodes to the channel region, regardless of the initial state. In this manner, the circuit shown in FIG. 9 becomes a NOR circuit. When the two input terminals are set at sufficiently low potentials, an electric field directed from the channel region to the gate electrodes is induced in the ferroelectric insulating films. Accordingly, the polarization is directed from the channel region to the gate electrodes, regardless of the initial state. In this manner, the circuit shown in FIG. 9 becomes a NAND circuit. As the gate electrodes of the semiconductor element 50 of the first embodiment can be connected to at least three different potentials, the circuit shown in FIG. 9 can be switched between a NOR circuit and a NAND circuit. Thus, a reconfigurable logic circuit can be formed with one element.

As mentioned in “Related Art”, a number of field effect transistors are required to form a reconfigurable logic circuit by a conventional technique, resulting in a very complicated structure.

With the use of the semiconductor element 50 of the first embodiment, on the other hand, a reconfigurable logic circuit can be formed very easily. This is also a fact discovered by the inventor of the present invention.

As described above, in a case where the two input terminals can be connected to a logic circuit, a sufficiently high potential, or a sufficiently low potential, the number of terminals that need to be switched for connection is two, which is the input terminals connected to the two gate electrodes. In a case where the terminal connected to the ground potential and the terminal connected to the power supply voltage can be connected to a logic circuit, a sufficiently high potential, or a sufficiently low potential, the number of terminals that need to be switched for connection is three, as determination needs to be made as to whether the output terminal is to be connected to the logic circuit. Therefore, the structure in which the two input terminals can be connected to a logic circuit, a sufficiently high potential, or a sufficiently low potential advantageously has a simpler circuit structure.

By a method of controlling the polarization of the ferroelectric insulating films by applying a sufficiently high potential or a sufficiently low potential to the two input terminals, it is necessary to control the polarization while there is a difference in potential between the source and the drain. Therefore, the electric field in the ferroelectric insulating films at the time of the polarization control has not only components vertical to the insulating films but also components in the direction of the source and the drain. As a result, the polarization has not only components vertical to the insulating films but also components in the direction of the source and the drain. In a case where the semiconductor element 50 shown in FIG. 9 is an n-type semiconductor element, a positive potential is applied to the drain in relation to the source, and accordingly, the polarization has components directed from the drain to the source. Positive polarization charges are then induced on the side face of each ferroelectric insulating film on the source side. Forming an electric field directed from the source to the drain, the induced charges hinder the current drivability of the semiconductor element 50.

In a case where the polarization of the ferroelectric insulating films is controlled by applying a sufficiently high potential or a sufficiently low potential to the terminal 74 connected to the ground potential and the terminal 75 connected to the power supply voltage of FIG. 9, the polarization of the ferroelectric insulating films is controlled while there is not a difference in potential between the source and the drain. Accordingly, hindrance to the current drivability is not caused as described above. Thus, high current drivability can be advantageously achieved.

Various changes and modifications as described in the first embodiment can also be made to this embodiment, to achieve the same effects as above.

### Third Embodiment

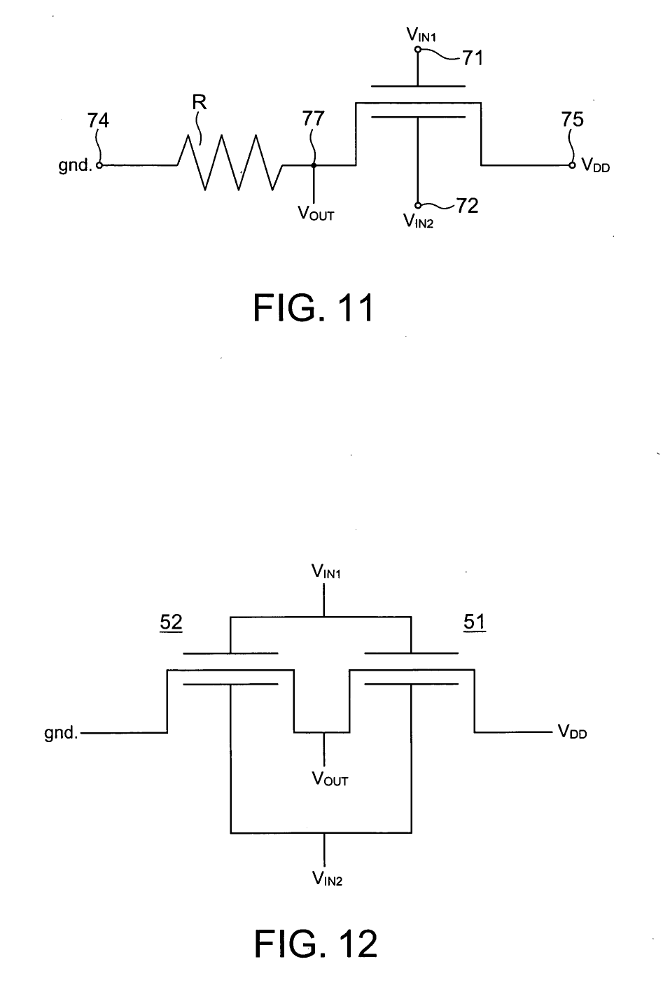

FIG. 11 illustrates a circuit in accordance with a third embodiment of the present invention. The circuit of this embodiment includes the semiconductor element 50 of the first embodiment and a resistor R. This semiconductor element 50 is a p-type semiconductor element, or a semiconductor element that has n-type impurities contained in the semiconductor region that serves as the channel and p-type impurities contained in the source/drain regions. The first and second gate electrodes of the semiconductor element 50 are connected to first and second input terminals 71 and 72, and potentials V_{IN1} and V_{IN2} are applied to the input terminals 71 and 72, respectively. One of the source/drain regions is connected to a potential terminal 75 of a power supply voltage, and the other one is connected to a ground terminal 74 via the resistor R. In FIG. 11, the ground potential is denoted by gnd., and the power supply voltage is denoted by V_{DD}. The source/drain regions and the resistor are connected with an output terminal 77, and the potential of the junction is denoted by V_{OUT}.

In a case where the polarization of the ferroelectric insulating films is directed from the gate electrodes to the channel region, the semiconductor element 50 becomes ON with a “NOR” of the two gate electrodes. Therefore, if both inputs are “0”, which is the ground potential, “1”, which is the power supply voltage, is output to the output terminal. In any other cases, “0”, which is the ground potential, is output to the output terminal. In this example case, the circuit of this embodiment is a NOR circuit.

To form a NOR circuit with conventional p-type field effect transistors, two p-type field effect transistors are connected in series, and a series-connected structure of the two p-type field effect transistors and a resistor is formed. Therefore, two field effect transistors are required.

In this embodiment, on the other hand, a NOR circuit can be formed only with one semiconductor element 50 of the first embodiment. Thus, this circuit can be formed through very simple procedures.

In a case where the polarization of the ferroelectric insulating films is directed from the channel region to the gate electrodes, the semiconductor element 50 becomes ON with a “NAND” of the two gate electrodes. Accordingly, if both inputs are “1”, which is the power supply voltage, “0”, which is the ground potential, is output to the output terminal. In any other cases, “1”, which is the power supply voltage, is output to the output terminal. Thus, this circuit becomes a NAND circuit.

To form a NAND circuit with conventional p-type field effect transistors, two p-type field effect transistors are connected in parallel, and a series-connected structure of the two p-type field effect transistors and a resistor is formed. Therefore, two field effect transistors are required.

In this embodiment, on the other hand, a NAND circuit can be formed only with one semiconductor element 50 of the first embodiment. Thus, this circuit can be formed through very simple procedures. This is a fact discovered by the inventor of the present invention.

The following example case is now described. The circuit of this embodiment is formed as a part of a logic circuit. The terminal connected to the ground potential and the terminal connected to the power supply voltage in the diagram can be connected to a sufficiently high potential and a sufficiently low potential. Determination is to be made as to whether the output terminal in the diagram is to be connected to the logic circuit.

When the connection between the output terminal and the logic circuit is cut off, and the terminal connected to the ground terminal and the terminal connected to the power supply voltage in the diagram are set at a sufficiently low potential, an electric field directed from the gate electrodes to the channel region is induced in the ferroelectric insulating films. Accordingly, the polarization is directed from the gate electrodes to the channel region, regardless of the initial state. In this manner, the circuit shown in FIG. 11 becomes a NOR circuit.

When the connection between the output terminal and the logic circuit is cut off, and the terminal connected to the ground terminal and the terminal connected to the power supply voltage in the diagram are set at a sufficiently high potential, an electric field directed from the channel region to the gate electrodes is induced in the ferroelectric insulating films. Accordingly, the polarization is directed from the channel region to the gate electrodes, regardless of the initial state. In this manner, the circuit shown in FIG. 11 becomes a NAND circuit.

As at least one of the source/drain terminals of the semiconductor element 50 of the first embodiment can be connected to at least three different potentials, the circuit shown in FIG. 11 can be switched between a NOR circuit and a NAND circuit. Thus, a reconfigurable logic circuit can be formed with one element.

As mentioned in “Related Art”, a number of field effect transistors are required to form a reconfigurable logic circuit by a conventional technique, resulting in a very complicated structure. With the use of the semiconductor element 50, on the other hand, a reconfigurable logic circuit can be formed very easily. This is also a fact discovered by the inventor of the present invention.

Next, the following example case is described. The circuit of this embodiment is formed as a part of a logic circuit. The two input terminals shown in the diagram can be connected to both a sufficiently high potential and a sufficiently low potential. When the two input terminals are set at sufficiently high potentials, an electric field directed from the gate electrodes to the channel region is induced in the ferroelectric insulating films. Accordingly, the polarization is directed from the gate electrodes to the channel region, regardless of the initial state. In this manner, the circuit shown in FIG. 11 becomes a NOR circuit.

When the two input terminals are set at sufficiently low potentials, an electric field directed from the channel region to the gate electrodes is induced in the ferroelectric insulating films. Accordingly, the polarization is directed from the channel region to the gate electrodes, regardless of the initial state. In this manner, the circuit shown in FIG. 11 becomes a NAND circuit.

As the gate electrodes of the semiconductor element 50 of the first embodiment can be connected to at least three different potentials, the circuit shown in FIG. 11 can be switched between a NOR circuit and a NAND circuit. Thus, a reconfigurable logic circuit can be formed with one element.

As mentioned in “Related Art”, a number of field effect transistors are required to form a reconfigurable logic circuit by a conventional technique, resulting in a very complicated structure. With the use of the semiconductor element 50 of the first embodiment, on the other hand, a reconfigurable logic circuit can be formed very easily. This is also a fact discovered by the inventor of the present invention.

Various changes and modifications as described in the foregoing embodiments can also be made to this embodiment, to achieve the same effects as above.

### Fourth Embodiment

FIG. 12 illustrates a circuit in accordance with a fourth embodiment of the present invention. The circuit of this embodiment includes semiconductor elements 51 and 52 connected in series. The semiconductor element 51 is a p-type semiconductor element of the first embodiment, or a semiconductor element that has n-type impurities contained in the semiconductor region that serves as the channel and p-type impurities contained in the source/drain regions. The semiconductor element 52 is an n-type semiconductor element of the first embodiment, or a semiconductor element that has p-type impurities contained in the semiconductor region that serves as the channel and n-type impurities contained in the source/drain regions. The p-type semiconductor element 51 is connected to a terminal of the power supply voltage, and the n-type semiconductor element 52 is connected to the ground potential. One of the first and second gate electrodes of each of the semiconductor elements 51 and 52 is connected to a first common input terminal, and the other one of the first and second gate electrodes is connected to a second common input terminal. In FIG. 12, the ground potential is denoted by gnd., and the power supply voltage is denoted by V_{DD}. The junction portion between the two semiconductor elements is connected to an output terminal, and the potential of the junction is denoted by V_{OUT}.

In a case where the polarization of the ferroelectric insulating films is directed from the gate electrodes to the channel region, the p-type semiconductor element 51 becomes ON with a “NOR” of the two gate electrodes, and the n-type semiconductor element 52 becomes ON with an “OR”. Therefore, if both inputs are “0”, which is the ground potential, “1”, which is the power supply voltage, is output. In any other cases, “0”, which is the ground potential, is output. In this example case, this circuit becomes a NOR circuit.

To form a NOR circuit with conventional complementary field effect transistors, two p-type field effect transistors are connected in series, and the series-connected p-type field effect transistors are series-connected to two n-type field effect transistors connected in parallel, so as to form a series-connected structure. Therefore, four field effect transistors are required.

In this embodiment, on the other hand, a NOR circuit can be formed only with two semiconductor elements of the first embodiment. Thus, this circuit can be formed through very simple procedures.

In a case where the polarization of the ferroelectric insulating films is directed from the channel region to the gate electrodes, the p-type semiconductor element 51 becomes ON with a “NAND” of the two gate electrodes, and the n-type semiconductor element 52 becomes ON with an “AND”. Accordingly, if both inputs are “1”, which is the power supply voltage, “0”, which is the ground potential, is output to the output terminal. In any other cases, “1”, which is the power supply voltage, is output to the output terminal. Thus, this circuit becomes a NAND circuit.

To form a NAND circuit with conventional complementary field effect transistors, two p-type field effect transistors are connected in parallel, and the parallel-connected field effect transistors are series-connected to two n-type field effect transistors connected in series, so as to form a series-connected structure. Therefore, four field effect transistors are required.

In this embodiment, on the other hand, a NAND circuit can be formed only with two semiconductor element of the first embodiment. Thus, this circuit can be formed through very simple procedures. This is a fact discovered by the inventor of the present invention.

The following example case is now described. The circuit of this embodiment is formed as a part of a logic circuit. The terminal connected to the ground potential and the terminal connected to the power supply voltage in the diagram can be connected to a sufficiently high potential and a sufficiently low potential. Determination is to be made as to whether the output terminal in the diagram is to be connected to the logic circuit. When the connection between the output terminal and the logic circuit is cut off, and the terminal connected to the ground terminal and the terminal connected to the power supply voltage in the diagram are set at a sufficiently low potential, an electric field directed from the gate electrodes to the channel region is induced in the ferroelectric insulating films. Accordingly, the polarization is directed from the gate electrodes to the channel region, regardless of the initial state. In this manner, the circuit shown in FIG. 12 becomes a NOR circuit.

When the connection between the output terminal and the logic circuit is cut off, and the terminal connected to the ground terminal and the terminal connected to the power supply voltage in the diagram are set at a sufficiently high potential, an electric field directed from the channel region to the gate electrodes is induced in the ferroelectric insulating films. Accordingly, the polarization is directed from the channel region to the gate electrodes, regardless of the initial state. In this manner, the circuit shown in FIG. 12 becomes a NAND circuit.

As at least one of the source/drain terminals of each semiconductor element of the first embodiment can be connected to at least three different potentials, the circuit shown in FIG. 12 can be switched between a NOR circuit and a NAND circuit. Thus, a reconfigurable logic circuit can be formed with two elements.

As mentioned in “Related Art”, a number of field effect transistors are required to form a reconfigurable logic circuit by a conventional technique, resulting in a very complicated structure.

With the use of the semiconductor elements of the first embodiment, on the other hand, a reconfigurable logic circuit can be formed very easily. This is also a fact discovered by the inventor of the present invention.

Next, the following example case is described. The circuit of this embodiment is formed as a part of a logic circuit. The two input terminals shown in the diagram can be connected to both a sufficiently high potential and a sufficiently low potential. When the two input terminals are set at sufficiently high potentials, an electric field directed from the gate electrodes to the channel region is induced in the ferroelectric insulating films. Accordingly, the polarization is directed from the gate electrodes to the channel region, regardless of the initial state. In this manner, the circuit shown in FIG. 12 becomes a NOR circuit.

When the two input terminals are set at sufficiently low potentials, an electric field directed from the channel region to the gate electrodes is induced in the ferroelectric insulating films. Accordingly, the polarization is directed from the channel region to the gate electrodes, regardless of the initial state. In this manner, the circuit shown in FIG. 12 becomes a NAND circuit.

As the gate electrodes of each semiconductor element of the first embodiment can be connected to at least three different potentials, the circuit shown in FIG. 12 can be switched between a NOR circuit and a NAND circuit. Thus, a reconfigurable logic circuit can be formed only with two elements.

As mentioned in “Related Art”, a number of field effect transistors are required to form a reconfigurable logic circuit by a conventional technique, resulting in a very complicated structure.

With the use of the semiconductor elements of the first embodiment, on the other hand, a reconfigurable logic circuit can be formed very easily. This is also a fact discovered by the inventor of the present invention.

In the circuit structure of the second embodiment illustrated in FIG. 9, current flows between the terminal connected to the power supply voltage and the terminal connected to the ground potential in the diagram when “0” is output. In the circuit structure of the third embodiment illustrated in FIG. 11, current flows between the terminal connected to the power supply voltage and the terminal connected to the ground potential when “1” is output.

In the circuit structure of this embodiment illustrated in FIG. 12, on the other hand, current does not flow between the terminal connected to the power supply voltage and the terminal connected to the ground potential in the diagram in any situation. Therefore, the circuit structure of this embodiment has an advantage to be able to reduce the power consumption. Meanwhile, each circuit structure of the second and third embodiments has an advantage in the simple circuit structure formed with one semiconductor element of the first embodiment.

Various changes and modifications as described in the foregoing embodiments can also be made to this embodiment, to achieve the same effects as above.

### Fifth Embodiment

Next, a semiconductor element in accordance with a fifth embodiment of the present invention is described.

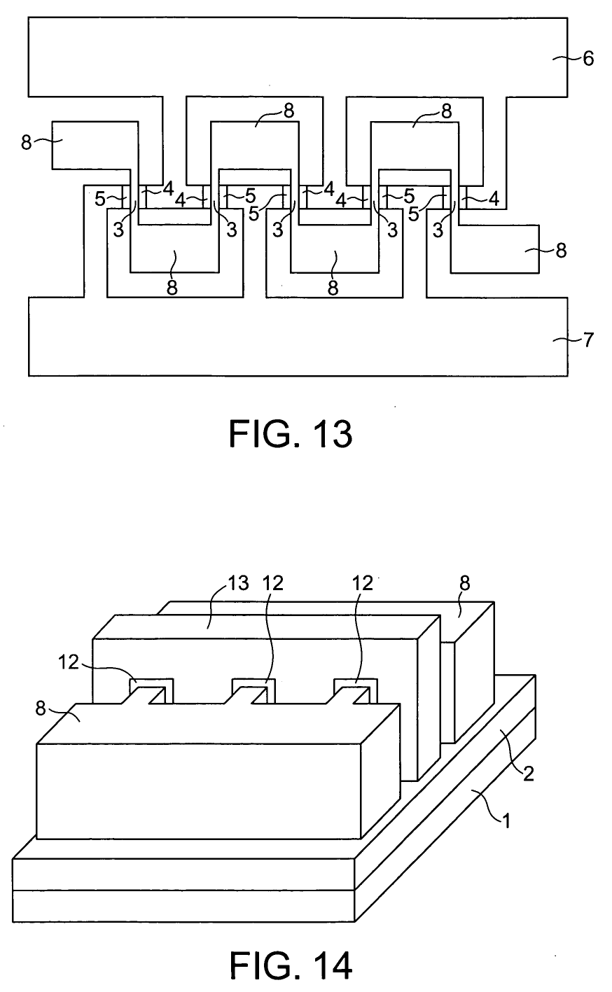

FIG. 13 is a cross-sectional view of a semiconductor element of this embodiment, taken in its horizontal direction. The operating principles of this semiconductor element are the same as those of the semiconductor elements of the foregoing embodiments. However, the semiconductor element of this embodiment is characterized by having two or more semiconductor regions 3 to form channel regions and two or more sets of source/drain regions 8. With this arrangement, there are two or more current flowing paths connecting the source/drain regions 8. Accordingly, compared with a structure having only one current flowing path, higher current drivability can be achieved, and the operating speed of the logic circuit can be increased.

In a case of a conventional Fin field effect transistor, the same potentials are applied to the gate electrodes formed at both sides of the semiconductor region that serves as a channel region. Therefore, to increase the current drivability, a structure schematically shown in FIG. 14 is produced so as to provide two or more channel regions.

In the semiconductor element of this embodiment, on the other hand, different potentials need to be applied to the gate electrodes formed at both sides of the semiconductor region that serves as a channel region. Therefore, the structure shown in FIG. 14 cannot realize such a function. Rather, it is necessary to form source regions 8 and drain regions 8 and form gate electrodes alternately, as schematically shown in the cross-sectional view of FIG. 13 taken in the parallel direction. Accordingly, to increase the current drivability with two or more channel regions in the semiconductor element of this embodiment, the formation of two or more sets of source/drain regions 8 is essential.

Various changes and modifications as described in the foregoing embodiments can also be made to this embodiment, to achieve the same effects as above.

As described so far, each embodiment of the present invention provides a highly-integrated, high-performance semiconductor device with a simplest possible structure.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a semiconductor element that includes
a first semiconductor region of a first conductivity type provided in a plate-like form on a semiconductor substrate; a first ferroelectric insulating film provided on a first side face of the first semiconductor region; a first gate electrode provided on the opposite face of the first ferroelectric insulating film from the first semiconductor region; a second ferroelectric insulating film provided on a second side face of the first semiconductor region; a second gate electrode provided on the opposite face of the second ferroelectric insulating film from the first semiconductor region; a channel region formed in the first semiconductor region and interposed between the first and second gate electrodes; and first source/drain regions of a second conductivity type provided at portions in the first semiconductor region located on both sides of the channel region,
the first semiconductor region having a thickness smaller than twice the largest thickness of a depletion layer that is determined by impurity concentration of the first semiconductor region.

2. The semiconductor device according to claim 1, wherein:
a current flowing through the first semiconductor region has a principal direction that is parallel to a surface of the semiconductor substrate; and
a direction extending from the first ferroelectric insulating film to the second ferroelectric insulating film via the first semiconductor region is parallel to the surface of the semiconductor substrate.

3. The semiconductor device according to claim 1, wherein at least one of the source/drain regions is connectable to at least three kinds of potential sources.

4. The semiconductor device according to claim 1, wherein one of the source/drain regions is connectable to a first potential source, while the other one of the source/drain regions is connectable to a second potential source having a different potential from the first potential source via a resistor.

5. The semiconductor device according to claim 4, wherein:
majority carriers of the first semiconductor region are holes; and
one of the source/drain regions is connectable to a power supply potential via a resistor, while the other one of the source/drain regions is connectable to a ground potential.

6. The semiconductor device according to claim 4, wherein:
majority carriers of the first semiconductor region are electrons; and
one of the source/drain regions is connectable to a ground potential via a resistor, while the other one of the source/drain regions is connectable to a power supply potential.

7. The semiconductor device according to claim 1, wherein each of the first gate electrode and the second gate electrode is connectable to at least three kinds of potential sources.

8. The semiconductor device according to claim 1, wherein there exist at least two first semiconductor regions.

9. The semiconductor device according to claim 8, wherein there exist at least two sets of first source/drain regions.

10. The semiconductor device according to claim 1, wherein the semiconductor element is a logic element.

11. The semiconductor device according to claim 1, wherein the first and second ferroelectric insulating films are made of one of PZT, PLZT, and SBT.

12. The semiconductor device according to claim 1, wherein the gate electrodes are made of metal.

13. A semiconductor device comprising:
a first semiconductor element and a second semiconductor element,
the first semiconductor element including: a first semiconductor region of a first conductivity type provided in a plate-like form on a semiconductor substrate; a first ferroelectric insulating film provided on a first side face of the first semiconductor region; a first gate electrode provided on the opposite face of the first ferroelectric insulating film from the first semiconductor region; a second ferroelectric insulating film provided on a second side face of the first semiconductor region; a second gate electrode provided on the opposite face of the second ferroelectric insulating film from the first semiconductor region; a first channel region formed in the first semiconductor region and interposed between the first and second gate electrodes; and first source/drain regions of a second conductivity type provided at portions in the first semiconductor region located on both sides of the first channel region,
the first semiconductor region having a thickness smaller than twice the largest thickness of a depletion layer that is determined by impurity concentration of the first semiconductor region,
the second semiconductor element including: a second semiconductor region of the second conductivity type provided in a plate-like form on the semiconductor substrate; a third ferroelectric insulating film provided on a first side face of the second semiconductor region; a third gate electrode provided on the opposite face of the third ferroelectric insulating film from the second semiconductor region; a fourth ferroelectric insulating film provided on a second side face of the second semiconductor region; a fourth gate electrode provided on the opposite face of the fourth ferroelectric insulating film from the second semiconductor region; a second channel region formed in the second semiconductor region and interposed between the third and fourth gate electrodes; and second source/drain regions of the first conductivity type provided at portions in the second semiconductor region located on both sides of the second channel region,
the second semiconductor region having a thickness smaller than twice the largest thickness of a depletion layer that is determined by impurity concentration of the second semiconductor region, and
one of the first source/drain regions being electrically connected to one of the second source/drain regions, one of the first and second gate electrodes being electrically connected to one of the third and fourth gate electrodes, the other one of the first and second gate electrodes being electrically connected to the other one of the third and fourth gate electrodes.

14. The semiconductor device according to claim 13, wherein one of the first source/drain regions and one of the second source/drain regions are connectable to at least three kinds of potential sources.

15. The semiconductor device according to claim 14, wherein majority carriers of the first semiconductor region are electrons, majority carriers of the second semiconductor region are holes, the one of the first source/drain regions is connectable to a power supply potential, and the one of the second source/drain regions is connectable to a ground potential.

16. The semiconductor device according to claim 13, wherein the first and second semiconductor elements are logic elements.

17. The semiconductor device according to claim 13, wherein the first through fourth ferroelectric insulating films are made of one of PZT, PLZT, and SBT.

18. The semiconductor device according to claim 13, wherein each of the first through fourth gate electrodes is connectable to at least three kinds of potential sources.

19. The semiconductor device according to claim 13, wherein there exist at least two first or second semiconductor regions.

20. The semiconductor device according to claim 19, wherein there exist at least two sets of first or second source/drain regions.
